(19) United States
(12) Patent Application Publication
(10) Pub. No.: US 2025/0162869 A1
(43) Pub. Date: May 22, 2025

(54) BISMUTH TELLURIDE-BASED MATERIAL WITH HIGH THERMOELECTRIC PERFORMANCE AND PREPARATION METHOD THEREFOR

(71) Applicants: Hailong He, Xi'an (CN); Mingzhe Rong, Xi'an (CN); Yi Wu, Xi'an (CN); Chunping Niu, Xi'an (CN); Tao Xiong, Xi'an (CN)

(72) Inventors: Hailong He, Xi'an (CN); Mingzhe Rong, Xi'an (CN); Yi Wu, Xi'an (CN); Chunping Niu, Xi'an (CN); Tao Xiong, Xi'an (CN)

(21) Appl. No.: 18/943,307

(22) Filed: Nov. 11, 2024

(30) Foreign Application Priority Data
Nov. 22, 2023 (CN) 2023115622730

(51) Int. Cl. C01B 19/00; H10N 10/01; H10N 10/852

(52) U.S. Cl. CPC C01B 19/002; H10N 10/01; H10N 10/852; C01P 2002/52; C01P 2006/32; C01P 2006/40

(57) ABSTRACT

Disclosed in the present disclosure are a P-type bismuth telluride-based material and a method for preparing the P-type bismuth telluride-based material. The P-type bismuth telluride-based material is doped with a rare earth element, and prepared from a rare earth material, a Sb source, a Te source and a Bi source by melting, ball milling and sintering. An outer layer atomic orbital of the rare earth element can greatly improve the energy band structure of a matrix phase. At the same time, a large atomic difference between a rare earth atom and a Sb atom is utilized to provide a mass potential field, enhancing the phonon scattering probability, and reducing lattice thermal conductivity, and the double action of the rare earth element synergistically enhances the thermoelectric performance of the P-type bismuth telluride-based material.

### CROSS-REFERENCE TO RELATED APPLICATION

This application claims priority from the Chinese patent application 2023115622730 filed Nov. 22, 2023, the content of which is incorporated herein in the entirety by reference.

### TECHNICAL FIELD

The present disclosure belongs to the technical field of energy materials, specifically belongs to the technical field of bismuth telluride-based materials, and relates to a bismuth telluride-based material and a preparation method therefor.

### BACKGROUND

Energy shortage and environmental pollution have become a great challenge that human beings need to face in the twenty-first century, as well as a major obstacle for human beings to move towards sustainable development. Therefore, the development of new energy materials and technologies is currently a main way to solve these two problems. Thermoelectric materials have the characteristics of environmental friendliness, recyclability, and mature preparation processes, and are more and more widely used in semiconductor refrigeration and waste heat recovery. Both refrigeration and power generation require the thermoelectric materials to have high thermoelectric performance at room temperature, so that a device can have excellent conversion efficiency.

Bismuth telluride-based materials have always been the best performing materials in a room temperature region, including thermoelectric power generation devices and refrigeration devices, and are also industrialized and mature thermoelectric materials. Both the conversion efficiency of the thermoelectric power generation devices and the cooling capacity of the refrigeration devices depend on a thermoelectric dimensionless thermoelectric figure of merit ZT of the thermoelectric materials, and increasing the ZT value in the room temperature range is the most fundamental way to increase the conversion efficiency of the devices.

A P-type bismuth telluride-based material on the market now has relatively good properties, and is currently the only commercially applied p-type thermoelectric material, and by means such as carrier control and nanometerization, relatively high low-temperature thermoelectric properties are obtained. However, at present, the ZT value of the industrialized P-type bismuth telluride-based material at room temperature is only maintained at about 1, which far limits the application of the materials; and in addition, the P-type bismuth telluride-based material has the technical problems of great processing difficulty and low yield.

In view of the above reasons, there is an urgent need to research a P-type bismuth telluride-based material having both excellent thermoelectric performance and simple processing methods.

### SUMMARY

In order to solve the above problems, the inventors conducted intensive research to develop a P-type bismuth telluride-based material and a preparation method therefor. The P-type bismuth telluride-based material uses Bi_{0.4}Sb_{1.6}Te₃ as a matrix, and the carrier concentration is adjusted by a rare earth element to enhance the carrier mobility. A general formula of the P-type bismuth telluride-based material is expressed as: Bi_{0.4}Sb_{1.6-x}MₓTe₃, wherein M is a rare earth element, and 0<x≤0.1, and the P-type bismuth telluride-based material is prepared from a rare earth element, a Sb source, a Te source and a Bi source by melting, ball-milling and sintering. An outer layer atomic orbital possessed by the rare earth element can greatly improve the energy band structure of a matrix phase. At the same time, a large atomic difference between a rare earth atom and a Sb atom is utilized to provide a mass potential field, enhancing the phonon scattering probability, and reducing lattice thermal conductivity, and the double action of the rare earth element synergistically enhances the thermoelectric performance of the P-type bismuth telluride-based material; and a sintered product is further subjected to thermal deformation treatment to improve carrier mobility. The method for preparing the P-type bismuth telluride-based material provided by the present disclosure is simple, and the P-type bismuth telluride-based material with high thermoelectric performance can be obtained only by in-situ doping with the rare earth element, providing an important technical guidance in optimizing the performance of a bismuth telluride-based thermoelectric material, thus completing the present disclosure.

In particular, an object of the present disclosure is to provide the following aspects:

in a first aspect, provided is a P-type bismuth telluride-based material doped with a rare earth element, the rare earth element being any one or more of La, Ce, Yb, and Lu.

The P-type bismuth telluride-based material specifically has a general formula as follows: Bi_{0.4}Sb_{1.6-x}MₓTe₃, wherein M is La, Ce, Yb, or Lu, and 0<x≤0.1.

The P-type bismuth telluride-based material is obtained from a rare earth material, a Sb source, a Te source and a Bi source by melting, ball milling and sintering.

In a second aspect, provided is a method for preparing a P-type bismuth telluride-based material, including melting a rare earth material, a Sb source, a Te source and a Bi source, and performing ball milling and sintering to prepare the P-type bismuth telluride-based material.

The rare earth material is a rare earth metal, the Sb source is an elementary substance Sb, the Te source is an elementary substance Te, and the Bi source is an elementary substance Bi.

The rare earth material, the Sb source, the Te source and the Bi source satisfy Bi_{0.4}Sb_{1.6-x}MₓTe₃, wherein M is a rare earth element, and 0<x≤0.1.

The melting is performed at a temperature of 650-950° C. for 4-12 h.

Mixing is performed once by shaking every other 0.2-2 h during the melting, and preferably, mixing is performed once by shaking every other 0.5-1.5 h during the melting.

The ball milling is performed at a rotational speed of 500-1100 rpm/min, preferably 600-1000 rpm/min for 20-150 min, preferably 30-120 min.

The sintering includes increasing the temperature to 330-370° C. under a vacuum degree of less than 10 Pa, then adjusting a sintering pressure to 20-70 MPa, increasing the temperature to 400-510° C., and performing heat preservation and pressure maintaining for 3-20 min. The beneficial effects of the present disclosure are as follows:

(1) the P-type bismuth telluride-based material provided by the present disclosure uses Bi_{0.4}Sb_{1.6}Te₃ as a matrix, and by doping with the rare earth element, the energy band structure of the P-type bismuth telluride-based material is improved by utilizing the valence electron structure of the rare earth atom, the carrier concentration is adjusted, and the carrier mobility is enhanced; a large atomic mass difference between the rare earth atom and the Sb atom provides a mass potential field, enhancing the phonon scattering probability, and reducing lattice thermal conductivity, and the double action of the rare earth atom synergistically enhances the thermoelectric performance of the P-type bismuth telluride-based material.

(2) The P-type bismuth telluride-based material provided by the present disclosure has a ZT value which is improved by 5-42% compared with the matrix Bi_{0.4}Sb_{1.6}Te₃, and the thermoelectric performance is significantly improved.

(3) According to the method for preparing the P-type bismuth telluride-based material provided by the present disclosure, a P-type bismuth telluride bulk material is subjected to secondary hot-pressing by employing a hot deformation process, so that grains in the P-type bismuth telluride bulk material are deformed during the secondary hot-pressing, and the growth arrangement and preferred orientation along the hot-pressing direction improve the carrier mobility, and its ZT value can be as high as 1.46 at 373 K.

(4) The method for preparing the P-type bismuth telluride-based material provided by the present disclosure is simple, and the P-type bismuth telluride-based material with high thermoelectric performance can be obtained only by in-situ doping with the rare earth element, providing an important technical guidance in optimizing the performance of a bismuth telluride-based thermoelectric material.

### BRIEF DESCRIPTION OF DRAWINGS

Various other advantages and benefits of the present disclosure will become apparent to those of ordinary skill in the art upon reading the following detailed description of the preferred embodiments. The drawings are only for the purpose of illustrating preferred embodiments and are not to be considered limiting of the present disclosure. Obviously, the drawings described below are merely some examples of the present disclosure, and for those of ordinary skill in the art, other drawings can also be obtained according to these drawings without inventive steps.

In the drawings:

FIG. 1 shows a graph comparing σ-T curves in Experimental example 1;

FIG. 2 shows a graph comparing S-T curves in Experimental example 1;

FIG. 3 shows a graph comparing κ-T curves in Experimental example 1; and

FIG. 4 shows a graph comparing ZT-T curves in Experimental example 1.

### DETAILED DESCRIPTION OF THE DISCLOSURE

Specific examples of the present disclosure will be described in more detail below with reference to the accompanying drawings 1 to 4. Although specific examples of the present disclosure are illustrated in the accompanying drawings, it should be understood that the present disclosure may be implemented in various forms and should not be construed as limited to the examples set forth herein. Rather, these examples are provided so that the present disclosure will be more thoroughly understood, and the scope of the present disclosure can be fully conveyed to those skilled in the art.

It should be noted that certain terms are used in the specification and claims to refer to specific components. It will be appreciated by those skilled in the art that different terms may be used to refer to the same component. The specification and claims do not use differences in terms as a way of distinguishing components, but rather use differences in function of components as criteria for distinguishing. “Comprising” or “including” mentioned throughout the specification and claims is an open-ended term, so it should be interpreted as “including but not limited to”. The subsequent description in the specification is preferred embodiments for implementing the present disclosure, but the description is for the purpose of general principles of the specification and is not intended to limit the scope of the present disclosure. The scope of protection of the present disclosure shall be construed as defined by the appended claims.

In order to facilitate the understanding of the examples of the present disclosure, further explanation will be given below by using specific examples as examples with reference to the accompanying drawings, and the accompanying drawings do not constitute a limitation of the examples of the present disclosure.

In one aspect, the present disclosure aims to provide a P-type bismuth telluride-based material doped with a rare earth element, the rare earth element being any one or more of La, Ce, Yb, and Lu, preferably the rare earth element being La, Ce, Yb or Lu, most preferably the rare earth element being Yb.

In the present disclosure, Bi_{0.4}Sb_{1.6}Te₃ is used as a matrix, and is doped with the rare earth element, i.e., the positions of Sb³⁺ are replaced by rare earth element ions of an outer layer atomic orbital of a part of atoms, by utilizing multivalent electron characteristics of the rare earth atom, the energy band structure of the matrix Bi_{0.4}Sb_{1.6}Te₃ is changed, and the carrier concentration of Bi_{0.4}Sb_{1.6}Te₃ is improved, so that its carrier concentration is obviously improved, thereby enhancing its electrical properties; at the same time, a large atomic difference between the rare earth element atom and the Sb atom and a large atomic diameter of the rare earth element atom itself can form an effective mass potential field, resulting in stronger phonon scattering, and effectively reducing lattice thermal conductivity, and through this synergistic effect, the ZT value of the P-type bismuth telluride-based material can reach 1.09 or more at 373 K, and further reach 1.46, and when the ZT value of the P-type bismuth telluride-based material reaches 1.46 at 373 K, the thermoelectric dimensionless thermoelectric figure of merit (ZT) is increased by 41.74% compared with Bi_{0.4}Sb_{1.6}Te₃.

An expression formula for the thermoelectric dimensionless thermoelectric figure of merit ZT is expressed as: ZT=S²σT/κ, where in the formula, S is the Seebeck coefficient, o is the electrical conductivity and x is the thermal conductivity, and T is the temperature.

Further, the P-type bismuth telluride-based material specifically has a general formula as follows: Bi_{0.4}Sb_{1.6-x}MₓTe₃, wherein M is a rare earth element, preferably La, Ce, Yb or Lu, most preferably Yb, 0<x≤0.1, preferably 0.0001≤x≤0.1, e.g., x is 0.006.

In the present disclosure, with the increase of the rare earth element content in the P-type bismuth telluride-based material, the ZT value of the P-type bismuth telluride-based material also increases, and when 0<x≤0.1, the P-type bismuth telluride-based material has excellent thermoelectric performance, and the thermoelectric performance of the P-type bismuth telluride-based material is the best in particular when x is 0.006.

According to the present disclosure, the P-type bismuth telluride-based material is obtained from a rare earth material, a Sb source, a Te source and a Bi source by melting, ball milling and sintering.

In another aspect, the present disclosure aims to provide a method for preparing the P-type bismuth telluride-based material in the first aspect, including melting a rare earth material, a Sb source, a Te source and a Bi source, and performing ball milling and sintering to prepare the P-type bismuth telluride-based material.

The rare earth material is a rare earth metal selected from any one or more of La, Ce, Yb, and Lu, preferably La, Ce, Yb, or Lu, most preferably Yb, the Sb source is an elementary substance Sb, the Te source is an elementary substance Te, and the Bi source is an elementary substance Bi, i.e., the high-purity elementary substance Bi, the high-purity rare earth metal, the high-purity elementary substance Sb, and the high-purity elementary substance Te are used to prepare crystals with a uniform composition.

In the present disclosure, Bi_{0.4}Sb_{1.6}Te₃ is used as a matrix and is modified, the inventors unexpectedly found that by doping with rare earth elements such as La, Ce, Yb, and Lu, the atomic difference and electronegativity difference between the doped rare earth element and the matrix element such as Sb form a large mass potential field; and since doping with large atoms such as La, Ce, Yb, and Lu will cause more point defects, dislocations and grain boundaries, the lattice thermal conductivity can be effectively reduced; in addition, the atomic structure of the rare earth element has a unique atomic orbital structure, which can induce the deep energy level excitation of the matrix material and improve the energy band structure, effectively adjust the carrier concentration, and enhance the carrier mobility, thereby achieving the purpose of decoupling between the electrical and thermal properties of the P-type bismuth telluride-based material, and improving the thermoelectric performance.

In the present disclosure, according to a stoichiometric ratio of Bi_{0.4}Sb_{1.6-x}MₓTe₃, the rare earth material, the Sb source, the Te source and the Bi source are weighed, mixed and melted; preferably, the rare earth material, the Sb source, the Te source and the Bi source are mixed and placed in a quartz tube with a vacuum degree of less than 10⁻³ Pa to be melt, preventing oxygen in air from causing oxidation of reactants and/or having an influence on a subsequent reaction.

As for Bi_{0.4}Sb_{1.6-x}MₓTe₃, M is a rare earth element, preferably La, Ce, Yb or Lu, most preferably Yb, 0<x≤0.1, preferably 0.0001≤x<0.1, e.g., x is 0.006.

According to the present disclosure, the melting is performed at a temperature of 650-950°° C., preferably 700-900° C., more preferably 850° C. for 4-12 h, preferably 5-10 h, more preferably 10 h.

In the present disclosure, the melting allows the reactants to be fine-grained in a short time. The inventors have found through research that too low or too high a temperature will deteriorate the thermoelectric performance of the prepared P-type bismuth telluride-based material; as the melting time is extended, the degree of alloying the reactants is more sufficient, which has a certain positive effect on improving the thermoelectric performance of the P-type bismuth telluride-based material, but too long a time is not necessary and may cause the thermoelectric performance of the P-type bismuth telluride based material to decrease. It is desirable when the melting temperature is 650-950° C. and the melting time is 4-12 h.

In the present disclosure, in order to further increase the degree of alloying of the reactants in the melting stage, optionally, mixing is performed once by shaking every other 0.2-2 h during the melting, and preferably, mixing is performed once by shaking every other 0.5-1.5 h during the melting, for example, mixing is performed once by shaking every other 1 h during the melting.

According to the present disclosure, a mixture obtained after the melting is subjected to ball milling, and the physical and chemical properties of the mixture will change during the ball milling. Under the external force of the ball milling, the dislocation density of the mixture continuously increases, resulting in gradual refinement of the mixture. The ball milling time and a rotational speed of the ball milling have an important impact on the energy and time of the ball milling. With the increase of the rotational speed of the ball milling, the collision and extrusion between the mixtures increases, and the refining effect is apparent; however, too much rotational speed of the ball milling will weaken the collision and extrusion of a ball milling medium on a ball milled material, which is unfavorable to improving the thermoelectric performance of the P-type bismuth telluride-based material. As the ball milling time increases, the density of the mixture increases and the carrier mobility increases; and when the ball milling time is too long, the mixture is prone to caking, which in turn leads to a decrease in conductivity.

Further, the ball milling is performed at a rotational speed of 500-1100 rpm/min, preferably 600-1000 rpm/min, more preferably 1000 rpm/min for 20-150 min, preferably 30-120 min, more preferably 30 min.

In the present disclosure, the more uniform the size of the P-type bismuth telluride-based material is, the better the effect is, powder obtained after the ball milling is allowed to pass through a 100- to 400-mesh sieve, preferably a 200- to 300-mesh sieve, for example, the powder obtained after the ball milling is allowed to pass through a 300-mesh sieve by using an ultrasonic sieving machine.

According to the present disclosure, the sintering is performed by gradually increasing the temperature, and include increasing the temperature to 330-370° C. under a vacuum degree of less than 10 Pa, then adjusting a sintering pressure to 20-70 MPa, increasing the temperature to 400-510° C., and performing heat preservation and pressure maintaining for 3-20 min.

Further, the sintering includes increasing the temperature to 340-360°° C. under a vacuum degree of less than 10 Pa, then adjusting the sintering pressure to 30-60 MPa, increasing the temperature to 450-500° C., and performing heat preservation and pressure maintaining for 5-15 min.

Still further, the sintering includes increasing the temperature to 350° C. under a vacuum degree of less than 10 Pa, then adjusting the sintering pressure to 60 MPa, increasing the temperature to 450° C., and performing heat preservation and pressure maintaining for 5 min.

Wherein gradually increasing the temperature can remove pores from the interior of a bulk in a low temperature phase, increasing the density of the material and increasing the electrical properties of the material. The sintering temperature has an important influence on the densification and microstructure of a P-type bismuth telluride bulk material obtained after sintering. When the sintering temperature is too low, the atomic diffusion driving force is small, which is not conducive to the densification of the P-type bismuth telluride bulk material, and grains in the P-type bismuth telluride bulk material are not sufficiently bonded; too high a sintering temperature may result in extrusion of low-melting-point components, resulting in non-uniform composition of the material and deteriorating the performance.

According to a preferred embodiment, a sintered product obtained after sintering is further subjected to a heat deformation treatment, the heat deformation treatment includes: increasing the temperature to 330-370° C. under a vacuum degree of less than 10 Pa, then adjusting a sintering pressure to 30-65 MPa, increasing the temperature to 480-550°° C., and performing heat preservation and pressure maintaining for 2-25 min; further preferably, the heat deformation treatment includes: increasing the temperature to 340-360°° C. under a vacuum degree of less than 10 Pa, then adjusting the sintering pressure to 40-60 MPa, increasing the temperature to 500-530° C., and performing heat preservation and pressure maintaining for 5-18 min; still more preferably, the heat deformation treatment includes: increasing the temperature to 350° C. under a vacuum degree of less than 10 Pa, then adjusting the sintering pressure to 60 MPa, increasing the temperature to 500° C., and performing heat preservation and pressure maintaining for 5 min.

According to the present disclosure, due to the influence of the crystal structure of bismuth telluride, the grains of bismuth telluride grow in flakes during the growth process. Therefore, there is anisotropy in thermoelectric performance along and perpendicular to the growth direction of a crystal plane, the grains will grow along the crystal plane with larger preferred orientation, and its preferred orientation is enhanced by a thermal deformation process, which is conducive to increasing the probability of in-plane orientation of the P-type bismuth telluride bulk material, increasing grain orientation, increasing carrier mobility, and enhancing the Seebeck coefficient characterizing the dimensionless thermoelectric figure of merit ZT. The ZT value of the P-type bismuth telluride-based material prepared with the heat deformation treatment step may be increased by 10% or more, even 26%, compared with a P-type bismuth telluride-based material prepared without the heat deformation treatment step.

### EXAMPLES

The present disclosure is further described below by means of specific examples, which are merely illustrative and do not limit the scope of protection of the present disclosure in any way.

### Example 1

0.2597 g of an elementary substance Yb, 2.7409 g of an elementary substance Sb, 5.745 g of an elementary substance Te and 1.2545 g of an elementary substance Bi were weighed sequentially, and filled into a clean reaction quartz tube according to a melting point from low to high, the tube was sealed under a vacuum degree of less than 10⁻³ Pa, then the reaction quartz tube was put into a muffle furnace, heating was performed to 850° C., heat preservation was performed for 10 h, the reaction quartz tube was shaken for mixing every other 1 h during the heat preservation, and then cooling was performed to room temperature to obtain a molten mixture;

the above molten mixture was subjected to high-speed planetary ball milling at a rotational speed of 1000 rpm/min for 30 min, and the ball milled material was allowed to pass through a 300-mesh sieve by an ultrasonic sieving machine to obtain powder having a particle size distribution range of less than 50 μm, and the powder was placed into a graphite mold having a diameter of 15 mm, and sintered in a discharge plasma sintering furnace according to the following procedures: increasing the temperature to 350° C. under a vacuum degree of less than 10 Pa, then adjusting the sintering pressure to 60 MPa, increasing the temperature to 450° C., performing heat preservation and pressure maintaining for 5 min, then performing cooling to room temperature, and taking out a sample to obtain a P-type bismuth telluride bulk material; and

the P-type bismuth telluride bulk material was put into a graphite mold having a diameter of 20 mm and subjected to a heat deformation treatment according to the following procedures: increasing the temperature to 350° C. under a vacuum degree of less than 10 Pa, then adjusting the sintering pressure to 60 MPa, increasing the temperature to 500° C., and performing heat preservation and pressure maintaining for 5 min to prepare the P-type bismuth telluride-based material having a chemical formula expressed as: Bi_{0.4}Sb_{1.5}Yb_{0.1}Te₃.

A ZT value of the prepared Bi_{0.4}Sb_{1.5}Yb_{0.1}Te₃ was measured to be 1.33 at 373 K.

### Example 2

0.0156 g of an elementary substance Yb, 2.9339 g of an elementary substance Sb, 5.787 g of an elementary substance Te and 1.2636 g of an elementary substance Bi were weighed sequentially, and filled into a clean reaction quartz tube according to a melting point from low to high, the tube was sealed under a vacuum degree of less than 10⁻³ Pa, then the reaction quartz tube was put into a muffle furnace, heating was performed to 850° C., heat preservation was performed for 10 h, the reaction quartz tube was shaken for mixing every other 1 h during the heat preservation, and then cooling was performed to room temperature to obtain a molten mixture;

the above molten mixture was subjected to high-speed planetary ball milling at a rotational speed of 1000 rpm/min for 30 min, and the ball milled material was allowed to pass through a 300-mesh sieve by an ultrasonic sieving machine to obtain powder having a particle size distribution range of less than 50 μm, and the powder was placed into a graphite mold having a diameter of 15 mm, and sintered in a discharge plasma sintering furnace according to the following procedures: increasing the temperature to 350° C. under a vacuum degree of less than 10 Pa, then adjusting the sintering pressure to 60 MPa, increasing the temperature to 450°° C., performing heat preservation and pressure maintaining for 5 min, then performing cooling to room temperature, and taking out a sample to obtain a P-type bismuth telluride bulk material; and

the P-type bismuth telluride bulk material was put into a graphite mold having a diameter of 20 mm and subjected to a heat deformation treatment according to the following procedures: increasing the temperature to 350° C. under a vacuum degree of less than 10 Pa, then adjusting the sintering pressure to 60 MPa, increasing the temperature to 500° C., and performing heat preservation and pressure maintaining for 5 min to prepare the P-type bismuth telluride-based material having a chemical formula expressed as: Bi_{0.4}Sb_{1.594}Yb_{0.006}Te₃.

A ZT value of the prepared Bi_{0.4}Sb_{1.594}Yb_{0.006}Te₃ was measured to be 1.46 at 373 K.

### Example 3

0.0261 g of an elementary substance Yb, 2.9257 g of an elementary substance Sb, 5.785 g of an elementary substance Te and 1.2632 g of an elementary substance Bi were weighed sequentially, and filled into a clean reaction quartz tube according to a melting point from low to high, the tube was sealed under a vacuum degree of less than 10-3 Pa, then the reaction quartz tube was put into a muffle furnace, heating was performed to 700°° C., heat preservation was performed for 5 h, the reaction quartz tube was shaken for mixing every other 1 h during the heat preservation, and then cooling was performed to room temperature to obtain a molten mixture;

the above molten mixture was subjected to high-speed planetary ball milling at a rotational speed of 600 rpm/min for 120 min, and the ball milled material was allowed to pass through a 300-mesh sieve by an ultrasonic sieving machine to obtain powder having a particle size distribution range of less than 50 μm, and the powder was placed into a graphite mold having a diameter of 15 mm, and sintered in a discharge plasma sintering furnace according to the following procedures: increasing the temperature to 350° C. under a vacuum degree of less than 10 Pa, then adjusting the sintering pressure to 30 MPa, increasing the temperature to 480°° C., performing heat preservation and pressure maintaining for 10 min, then performing cooling to room temperature, and taking out a sample to obtain a P-type bismuth telluride bulk material; and

the P-type bismuth telluride bulk material was put into a graphite mold having a diameter of 20 mm and subjected to a heat deformation treatment according to the following procedures: increasing the temperature to 350° C. under a vacuum degree of less than 10 Pa, then adjusting the sintering pressure to 30 MPa, increasing the temperature to 500°° C., and performing heat preservation and pressure maintaining for 5 min to prepare the P-type bismuth telluride-based material having a chemical formula expressed as: Bi_{0.4}Sb_{1.59}Yb_{0.01}Te₃.

A ZT value of the prepared Bi_{0.4}Sb_{1.59}Yb_{0.01}Te₃ was measured to be 1.09 at 373 K.

### Example 4

0.0522 g of an elementary substance Yb, 2.905 g of an elementary substance Sb, 5.78 g of an elementary substance Te, and 1.2622 g of an elementary substance Bi were weighed sequentially, and filled into a clean reaction quartz tube according to a melting point from low to high, the tube was sealed under a vacuum degree of less than 10⁻³ Pa, then the reaction quartz tube was put into a muffle furnace, heating was performed to 800°° C., heat preservation was performed for 8 h, the reaction quartz tube was shaken for mixing every other 1 h during the heat preservation, and then cooling was performed to room temperature to obtain a molten mixture;

the above molten mixture was subjected to high-speed planetary ball milling at a rotational speed of 800 rpm/min for 80 min, and the ball milled material was allowed to pass through a 300-mesh sieve by an ultrasonic sieving machine to obtain powder having a particle size distribution range of less than 50 μm, and the powder was placed into a graphite mold having a diameter of 15 mm, and sintered in a discharge plasma sintering furnace according to the following procedures: increasing the temperature to 350° C. under a vacuum degree of less than 10 Pa, then adjusting the sintering pressure to 50 MPa, increasing the temperature to 460° C., performing heat preservation and pressure maintaining for 15 min, then performing cooling to room temperature, and taking out a sample to obtain a P-type bismuth telluride bulk material; and

the P-type bismuth telluride bulk material was put into a graphite mold having a diameter of 20 mm and subjected to a heat deformation treatment according to the following procedures:

increasing the temperature to 350° C. under a vacuum degree of less than 10 Pa, then adjusting the sintering pressure to 50 MPa, increasing the temperature to 520° C., and performing heat preservation and pressure maintaining for 5 min to prepare the P-type bismuth telluride-based material having a chemical formula expressed as: Bi_{0.4}Sb_{1.58}Yb_{0.02}Te₃.

A ZT value of the prepared Bi_{0.4}Sb_{1.58}Yb_{0.02}Te₃ was measured to be 1.13 at 373 K.

### Example 5

0.1303 g of an elementary substance Yb, 2.8433 g of an elementary substance Sb, 5.767 g of an elementary substance Te and 1.2593 g of an elementary substance Bi were weighed sequentially, and filled into a clean reaction quartz tube according to a melting point from low to high, the tube was sealed under a vacuum degree of less than 10-3 Pa, then the reaction quartz tube was put into a muffle furnace, heating was performed to 900° C., heat preservation was performed for 8 h, the reaction quartz tube was shaken for mixing every other 1 h during the heat preservation, and then cooling was performed to room temperature to obtain a molten mixture;

the above molten mixture was subjected to high-speed planetary ball milling at a rotational speed of 750 rpm/min for 100 min, and the ball milled material was allowed to pass through a 200-mesh sieve by an ultrasonic sieving machine to obtain powder having a particle size distribution range of less than 80 μm, and the powder was placed into a graphite mold having a diameter of 15 mm, and sintered in a discharge plasma sintering furnace according to the following procedures: increasing the temperature to 350°° C. under a vacuum degree of less than 10 Pa, then adjusting the sintering pressure to 40 MPa, increasing the temperature to 500°° C., performing heat preservation and pressure maintaining for 8 min, then performing cooling to room temperature, and taking out a sample to obtain a P-type bismuth telluride bulk material; and

the P-type bismuth telluride bulk material was put into a graphite mold having a diameter of 20 mm and subjected to a heat deformation treatment according to the following procedures: increasing the temperature to 350° C. under a vacuum degree of less than 10 Pa, then adjusting the sintering pressure to 40 MPa, increasing the temperature to 530° C., and performing heat preservation and pressure maintaining for 5 min to prepare the P-type bismuth telluride-based material having a chemical formula expressed as: Bi_{0.4}Sb_{1.55}Yb_{0.05}Te₃.

A ZT value of the prepared Bi_{0.4}Sb_{1.55}Yb_{0.05}Te₃ was measured to be 1.19 at 373 K.

### Example 6

0.0105 g of an elementary substance La, 2.9224 g of an elementary substance Sb, 5.8 g of an elementary substance Te and 1.2666 g of an elementary substance Bi were weighed sequentially, and filled into a clean reaction quartz tube according to a melting point from low to high, the tube was sealed under a vacuum degree of less than 10⁻³ Pa, then the reaction quartz tube was put into a muffle furnace, heating was performed to 850° C., heat preservation was performed for 10 h, the reaction quartz tube was shaken for mixing every other 1 h during the heat preservation, and then cooling was performed to room temperature to obtain a molten mixture;

the above molten mixture was subjected to high-speed planetary ball milling at a rotational speed of 1000 rpm/min for 30 min, and the ball milled material was allowed to pass through a 300-mesh sieve by an ultrasonic sieving machine to obtain powder having a particle size distribution range of less than 50 μm, and the powder was placed into a graphite mold having a diameter of 15 mm, and sintered in a discharge plasma sintering furnace according to the following procedures: increasing the temperature to 350° C. under a vacuum degree of less than 10 Pa, then adjusting the sintering pressure to 60 MPa, increasing the temperature to 450°° C., performing heat preservation and pressure maintaining for 5 min, then performing cooling to room temperature, and taking out a sample to obtain a P-type bismuth telluride bulk material; and

the P-type bismuth telluride bulk material was put into a graphite mold having a diameter of 20 mm and subjected to a heat deformation treatment according to the following procedures: increasing the temperature to 350° C. under a vacuum degree of less than 10 Pa, then adjusting the sintering pressure to 60 MPa, increasing the temperature to 500° C., and performing heat preservation and pressure maintaining for 5 min to prepare the P-type bismuth telluride-based material having a chemical formula expressed as: Bi_{0.4}Sb_{1.595}La_{0.005}Te₃.

A ZT value of the prepared Bi_{0.4}Sb_{1.595}La_{0.005}Te₃ was measured to be 1.38 at 373 K.

### Example 7

0.0106 g of an elementary substance Ce, 2.9224 g of an elementary substance Sb, 5.8 g of an elementary substance Te and 1.2666 g of an elementary substance Bi were weighed sequentially, and filled into a clean reaction quartz tube according to a melting point from low to high, the tube was sealed under a vacuum degree of less than 10⁻³ Pa, then the reaction quartz tube was put into a muffle furnace, heating was performed to 850° C., heat preservation was performed for 10 h, the reaction quartz tube was shaken for mixing every other 1 h during the heat preservation, and then cooling was performed to room temperature to obtain a molten mixture;

the above molten mixture was subjected to high-speed planetary ball milling at a rotational speed of 1000 rpm/min for 30 min, and the ball milled material was allowed to pass through a 300-mesh sieve by an ultrasonic sieving machine to obtain powder having a particle size distribution range of less than 50 μm, and the powder was placed into a graphite mold having a diameter of 15 mm, and sintered in a discharge plasma sintering furnace according to the following procedures: increasing the temperature to 350° C. under a vacuum degree of less than 10 Pa, then adjusting the sintering pressure to 60 MPa, increasing the temperature to 450° C., performing heat preservation and pressure maintaining for 5 min, then performing cooling to room temperature, and taking out a sample to obtain a P-type bismuth telluride bulk material; and

the P-type bismuth telluride bulk material was put into a graphite mold having a diameter of 20 mm and subjected to a heat deformation treatment according to the following procedures: increasing the temperature to 350° C. under a vacuum degree of less than 10 Pa, then adjusting the sintering pressure to 60 MPa, increasing the temperature to 500°° C., and performing heat preservation and pressure maintaining for 5 min to prepare the P-type bismuth telluride-based material having a chemical formula expressed as: Bi_{0.4}Sb_{1.595}Ce_{0.005}Te₃.

A ZT value of the prepared Bi_{0.4}Sb_{1.595}Ce_{0.005}Te₃ was measured to be 1.36 at 373 K.

### COMPARATIVE EXAMPLES

### Comparative Example 1

2.9463 g of an elementary substance Sb, 5.789 g of an elementary substance Te and 1.2642 g of an elementary substance Bi were weighed sequentially, and filled into a clean reaction quartz tube according to a melting point from low to high, the tube was sealed under a vacuum degree of less than 10⁻³ Pa, then the reaction quartz tube was put into a muffle furnace, heating was performed to 850°° C., heat preservation was performed for 10 h, the reaction quartz tube was shaken for mixing every other 1 h during the heat preservation, and then cooling was performed to room temperature to obtain a molten mixture;

the above molten mixture was subjected to high-speed planetary ball milling at a rotational speed of 1000 rpm/min for 30 min, and the ball milled material was allowed to pass through a 300-mesh sieve by an ultrasonic sieving machine to obtain powder having a particle size distribution range of less than 50 μm, and the powder was placed into a graphite mold having a diameter of 15 mm, and sintered in a discharge plasma sintering furnace according to the following procedures: increasing the temperature to 350° C. under a vacuum degree of less than 10 Pa, then adjusting the sintering pressure to 60 MPa, increasing the temperature to 450° C., performing heat preservation and pressure maintaining for 5 min, then performing cooling to room temperature, and taking out a sample to obtain a P-type bismuth telluride bulk material; and

the P-type bismuth telluride bulk material was put into a graphite mold having a diameter of 20 mm and subjected to a heat deformation treatment according to the following procedures: increasing the temperature to 350° C. under a vacuum degree of less than 10 Pa, then adjusting the sintering pressure to 60 MPa, increasing the temperature to 500° C., and performing heat preservation and pressure maintaining for 5 min to prepare the P-type bismuth telluride-based material having a chemical formula expressed as: Bi_{0.4}Sb_{1.6}Te₃.

A ZT value of the prepared Bi_{0.4}Sb_{1.6}Te₃ was measured to be 1.03 at 373 K.

### Comparative Example 2

A P-type bismuth telluride-based material Bi_{0.4}Sb_{1.5}Yb_{0.1}Te₃ was prepared in a similar manner to that in Example 1, except that no heat deformation treatment was performed.

A ZT value of the prepared Bi_{0.4}Sb_{1.5}Yb_{0.1}Te₃ was measured to be 1.05 at 375 K.

### EXPERIMENTAL EXAMPLE

### Experimental Example 1

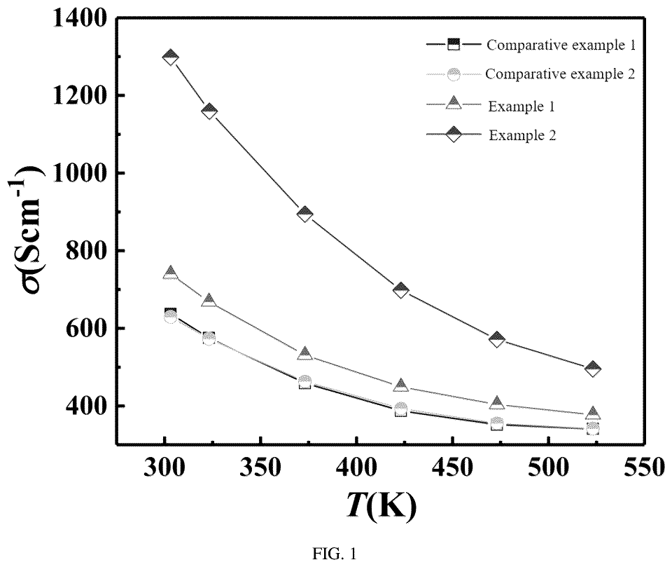

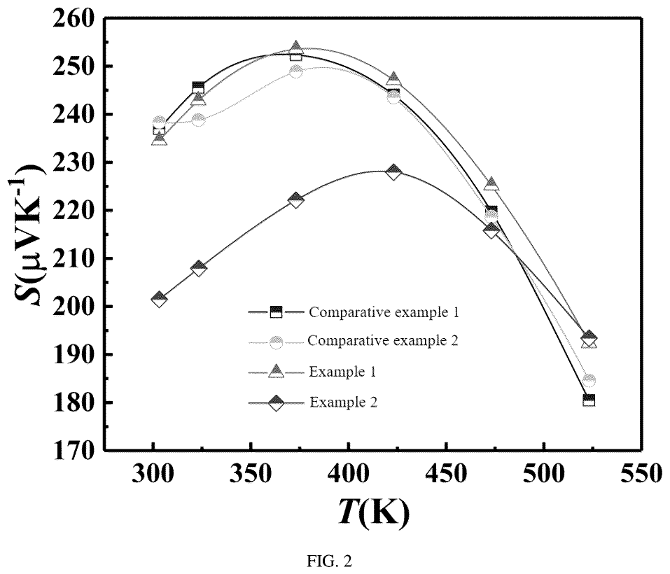

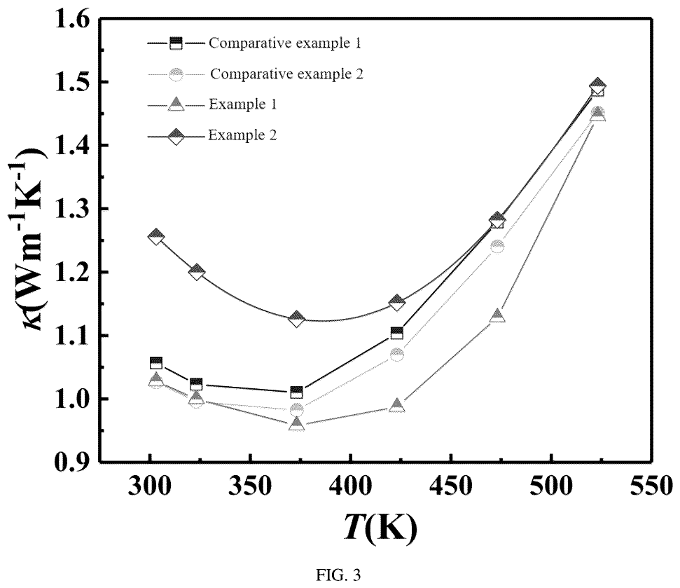

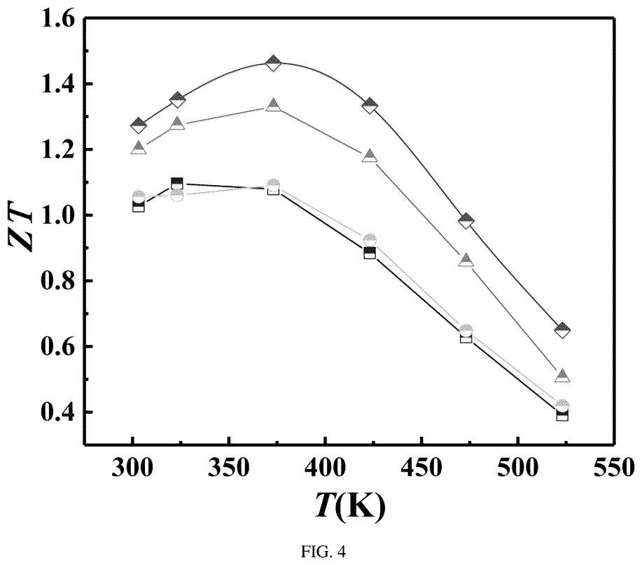

The P-type bismuth telluride-based materials prepared in Example 1, Example 2, Comparative example 1 and Comparative example 2 were processed into bulk samples of 3×3×12 mm, respectively, and electrical properties were tested after polishing and grinding; the P-type bismuth telluride-based materials prepared in Example 1, Comparative example 1 and Comparative example 2 were processed into bulk samples of 6×6×2 mm, respectively, and thermal properties were tested after polishing and grinding, and the results are shown in FIGS. 1 to 4, wherein FIG. 1 shows a graph comparing σ-T curves of the P-type bismuth telluride-based materials prepared in Examples 1-2 and Comparative examples 1-2, and FIG. 2 shows a graph comparing S-T curves of the P-type bismuth telluride-based materials prepared in Examples 1-2 and Comparative examples 1-2; FIG. 3 shows a graph comparing κ-T curves of the P-type bismuth telluride-based materials prepared in Examples 1-2 and Comparative examples 1-2; and FIG. 4 shows a graph comparing ZT-T curves of the P-type bismuth telluride-based materials prepared in Examples 1-2 and Comparative examples 1-2.

As can be seen from the figures: compared with Comparative example 1, in Example 1, the carrier concentration and mobility are increased by doping with the rare earth element, i.e., the Yb atom; and the mass potential field formed by the large atomic difference causes the scattering probability of its phonons, which is conducive to the decrease of the thermal conductivity of the P-type bismuth telluride-based material, and the decoupling of the thermoelectric parameters of the P-type bismuth telluride-based material is strengthened by the synergistic effect, so that the ZT value of the P-type bismuth telluride-based material is increased by 29% compared with Comparative example 1. As can be seen from Examples 1 and 2, decreasing the doping amount of the rare earth element can change the energy band structure of the matrix phase, greatly enhance the electrical properties of the material, and increase its ZT value by 41.74% compared with Comparative example 1, greatly improving the thermoelectric performance of the P-type bismuth telluride-based material.

By comparing Example 1 with Comparative example 2, due to being limited by the crystal structure of the P-type bismuth telluride-based material, there will be anisotropy in the growth process, and the grains will grow along a crystal plane with larger preferred orientation, and its preferred orientation is enhanced by a thermal deformation process, which is conducive to increasing the probability of in-plane orientation of the P-type bismuth telluride bulk material, increasing grain orientation, increasing carrier mobility, and enhancing the Seebeck coefficient. The technical solution of Example 1 can effectively enhance the performance of the P-type bismuth telluride-based material so that its ZT value reaches 1.33 at 373 K. It is demonstrated by Example 1 and Comparative example 2 that enhancing the anisotropy of the P-type bismuth telluride-based material plays a key role in enhancing the mobility and thermoelectric performance of the P-type bismuth telluride-based material.

The present disclosure has been described in detail above with reference to preferred embodiments and illustrative examples. However, it should be noted that these specific embodiments are merely illustrative of the present disclosure and do not limit the scope of protection of the present disclosure in any way. Various improvements, equivalent replacements or modifications can be made to the technical contents of the present disclosure and the embodiments thereof without departing from the spirit and protection scope of the present disclosure, and all fall within the scope of protection of the present disclosure. The scope of protection of the present disclosure is subject to the appended claims.

1. A P-type bismuth telluride-based material, wherein the P-type bismuth telluride-based material is doped with a rare earth element, wherein the rare earth element is any one or more of La, Ce, Yb, and Lu.

2. The P-type bismuth telluride-based material according to claim 1, wherein preferably, the P-type bismuth telluride-based material specifically has a general formula as follows: Bi_{0.4}Sb_{1.6-x}MₓTe₃, wherein M is La, Ce, Yb, or Lu, and 0<x≤0.1.

3. The P-type bismuth telluride-based material according to claim 1, wherein the P-type bismuth telluride-based material is obtained from a rare earth material, a Sb source, a Te source and a Bi source by melting, ball milling and sintering.

4. A method for preparing a P-type bismuth telluride-based material, comprising:
melting a rare earth material, a Sb source, a Te source and a Bi source, and performing ball milling and sintering to prepare the P-type bismuth telluride-based material.

5. The method according to claim 4, wherein the rare earth material is a rare earth metal, the Sb source is an elementary substance Sb, the Te source is an elementary substance Te, and the Bi source is an elementary substance Bi.

6. The method according to claim 4, wherein the rare earth material, the Sb source, the Te source and the Bi source satisfy Bi_{0.4}Sb_{1.6-x}MₓTe₃, wherein M is a rare earth element, and 0<x≤0.1.

7. The method according to claim 4, wherein the melting is performed at a temperature of 650-950° C. for 4-12 h.

8. The method according to claim 4, wherein mixing is performed once by shaking every other 0.2-2 h during the melting, and preferably, mixing is performed once by shaking every other 0.5-1.5 h during the melting.

9. The method according to claim 4, wherein the ball milling is performed at a rotational speed of 500-1100 rpm/min, preferably 600-1000 rpm/min for 20-150 min, preferably 30-120 min.

10. The method according to claim 4, wherein the sintering comprises increasing the temperature to 330-370° C. under a vacuum degree of less than 10 Pa, then adjusting a sintering pressure to 20-70 MPa, increasing the temperature to 400-510° C., and performing heat preservation and pressure maintaining for 3-20 min.

11. The P-type bismuth telluride-based material according to claim 2, wherein the P-type bismuth telluride-based material is obtained from a rare earth material, a Sb source, a Te source and a Bi source by melting, ball milling and sintering.

12. The method according to claim 5, wherein the rare earth material, the Sb source, the Te source and the Bi source satisfy Bi_{0.4}Sb_{1.6-x}MₓTe₃, wherein M is a rare earth element, and 0<x≤0.1.
